(19) United States
(12) Patent Application Publication
(10) Pub. No.: US 2025/0279378 A1
(43) Pub. Date: Sep. 4, 2025

(54) SEMICONDUCTOR ELEMENT AND SEMICONDUCTOR DEVICE

(71) Applicant: Rohm Co., Ltd., Kyoto-shi (JP)

(72) Inventor: Manato KURATA, Kyoto-shi (JP)

(21) Appl. No.: 19/068,484

(22) Filed: Mar. 3, 2025

(30) Foreign Application Priority Data
Mar. 4, 2024 (JP) 2024-032148

(51) Int. Cl. H01L 23/00

(52) U.S. Cl. CPC H01L 24/05; H01L 24/02; H01L 24/13; H01L 24/16; H01L 2224/02381; H01L 2224/05008; H01L 2224/05017; H01L 2224/05022; H01L 2224/05073; H01L 2224/05548; H01L 2224/05552; H01L 2224/05557; H01L 2224/05567; H01L 2224/05569; H01L 2224/05573; H01L 2224/05655; H01L 2224/13111; H01L 2224/16227; H01L 2224/16238; H01L 2924/3511

(57) ABSTRACT

A semiconductor element includes a main body with a semiconductor layer, an electrode located on one side of the main body in a first direction and electrically conducting to the semiconductor layer, a terminal opposite to the main body with respect to the electrode in the first direction and electrically conducting to the electrode, and a metal bonding layer electrically conducting to the terminal. The terminal includes a first surface facing a side where the electrode is located in the first direction, and an opposite second surface. The bonding layer is opposite to the first surface across the second surface. In a second direction orthogonal to the first direction, the dimension of the periphery of the first surface is not less than 40% and not greater than 60% of the dimension of the periphery of the second surface.

### FIELD

The present disclosure relates to a semiconductor element, and a semiconductor device in which the semiconductor element is mounted.

### BACKGROUND

JP-A-2014-165335 discloses an example of a semiconductor element (a semiconductor device in this patent document). The semiconductor element has a substrate having an element formation surface, a pad terminal provided on the element formation surface, a passivation film covering a portion of the pad terminal and the element formation surface, a Cu redistribution wiring extending out from the pad terminal, an organic film covering the Cu redistribution wiring, and a resin film covering the organic film. The surface of the Cu redistribution wiring includes a roughened surface. The organic film is in contact with the roughened surface. With such a configuration, an anchoring effect for the Cu redistribution wiring is generated in the organic film. Furthermore, because the affinity between the organic film and the resin film is relatively high, the adhesion of the resin film to the organic film is enhanced. This suppresses separation of the resin film from the Cu redistribution wiring.

The semiconductor element disclosed in JP-A-2014-165335 further includes a terminal electrically conducting to the Cu redistribution wiring, and a bonding layer on the terminal. In the semiconductor element, electromigration due to the current density in the terminal affects the bonding layer. If the degree of electromigration is relatively large, there is a risk that cracks will occur in the bonding layer.

### DRAWINGS

FIG. 1 is a plan view of a semiconductor element according to a first embodiment of the present disclosure.

FIG. 2 is a partial enlarged view of FIG. 1, in which a bonding layer is transparent.

FIG. 3 is a sectional view taken along line III-III in FIG. 2.

FIG. 4 is a sectional view taken along line IV-IV in FIG. 2.

FIG. 5 is a graph for describing the effects of the semiconductor element shown in FIG. 1.

FIG. 6 is a sectional view of a semiconductor device in which the semiconductor element shown in FIG. 1 is mounted.

FIG. 7 is a partial enlarged sectional view corresponding to FIG. 3, showing a semiconductor element according to a second embodiment of the present disclosure.

FIG. 8 is a graph for describing the effects of the semiconductor element shown in FIG. 7.

FIG. 9 is a partial enlarged sectional view corresponding to FIG. 3, showing a semiconductor element according to a third embodiment of the present disclosure.

FIG. 10 is a partial enlarged plan view corresponding to FIG. 2, showing a semiconductor element according to a fourth embodiment of the present disclosure.

FIG. 11 is a sectional view taken along line XI-XI in FIG. 10.

FIG. 12 is a sectional view of a semiconductor element according to a fifth embodiment of the present disclosure.

### EMBODIMENTS

The details of the present disclosure will be described based on the accompanying drawings.

### First Embodiment

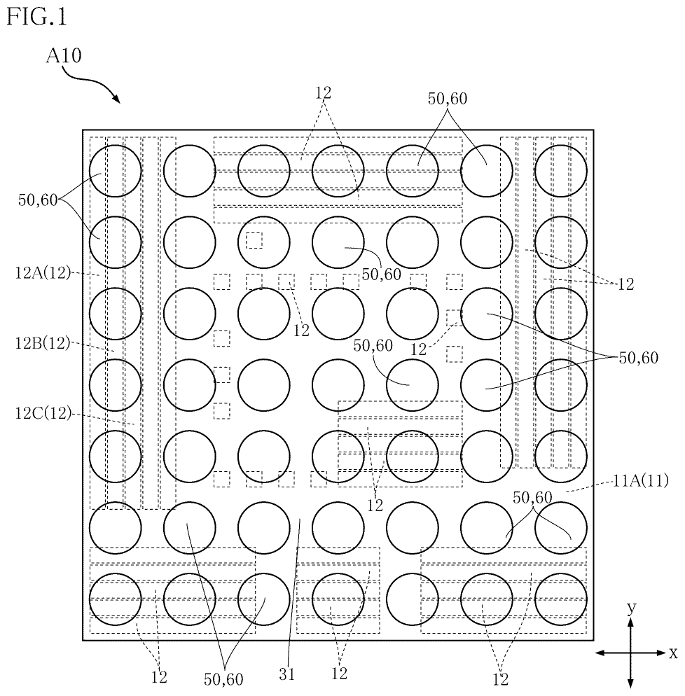

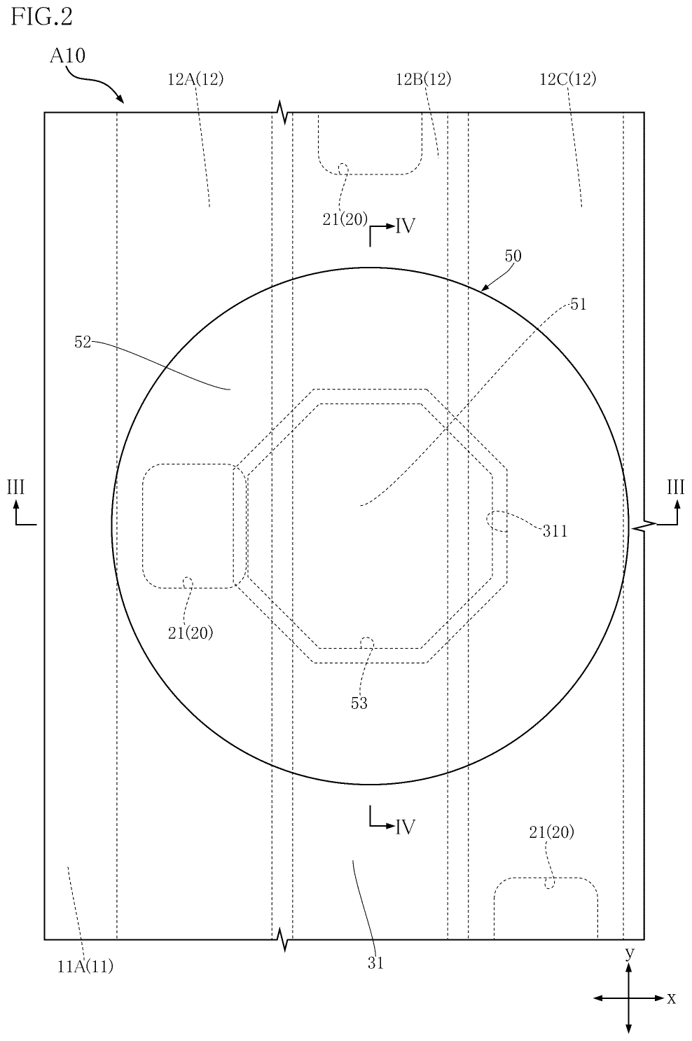

A semiconductor element A10 according to a first embodiment of the present disclosure will be described based on FIGS. 1 to 5. The semiconductor element A10 is, for example, an LSI (Large Scale Integration) referred to as a Wafer Level-Chip Size Package (WL-CSP). The semiconductor element A10 includes a main body 11, a plurality of electrodes 12, a passivation film 20, a first protective film 31, a second protective film 32, a plurality of redistribution wirings 40, a plurality of terminals 50, and a plurality of bonding layers 60. For the convenience of understanding, the bonding layer 60 is transparent in FIG. 2.

In the description of the semiconductor element A10 and a semiconductor device B that will be described later, the direction that is normal to the obverse surface 11A of the main body 11, described later, is referred to as the “first direction z”. A direction orthogonal to the first direction z is referred to as the “second direction x”. The direction orthogonal to each of the first direction z and the second direction z is referred to as the “third direction y”.

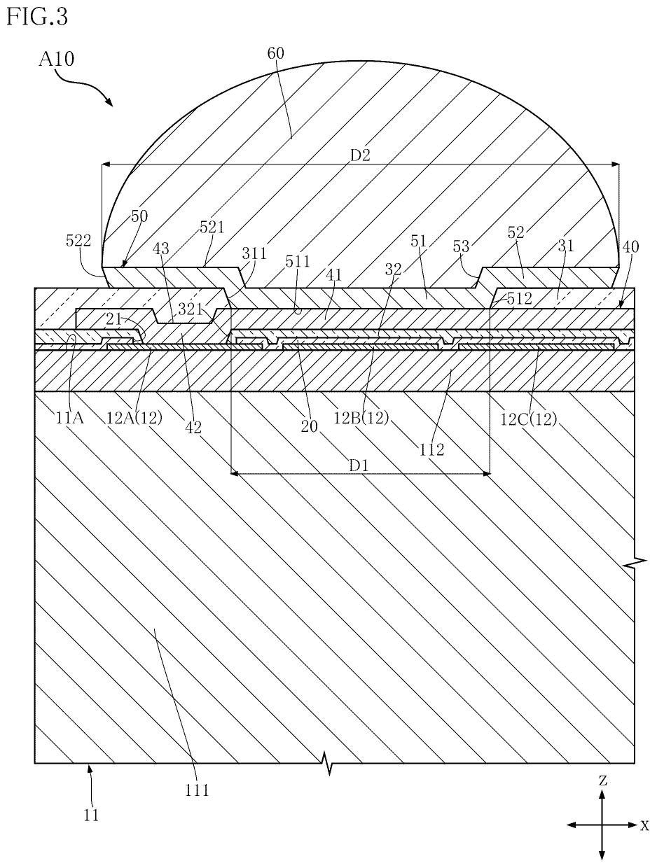

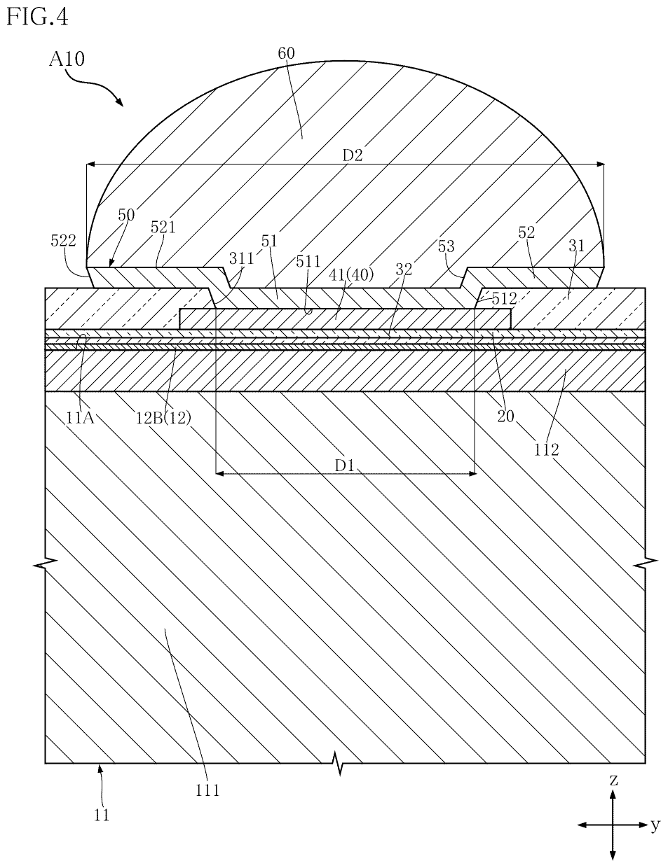

As shown in FIGS. 3 and 4, the main body 11 includes a semiconductor substrate 111 and a semiconductor layer 112 located on one side of the semiconductor substrate 111 in the first direction z. The main body 11 has an obverse surface 11A facing the above-mentioned one side in the first direction z. The semiconductor layer 112 includes the obverse surface 11A. The semiconductor substrate 111 is made from a silicon wafer, for example. Various semiconductor circuits, such as transistors and diodes, are configured on or near the obverse surface 11A of the semiconductor layer 112.

As shown in FIGS. 3 and 4, the plurality of electrodes 12 are located on the above-mentioned one side of the main body 11 in the first direction z. The electrodes 12 are in contact with the obverse surface 11A of the main body 11. The electrodes 12 electrically conduct to various semiconductor circuits configured on the semiconductor layer 112. The electrodes 12 contain aluminum (Al), for example. The configurations, such as the arrangement and shapes, of the electrodes 12 in the present disclosure are merely examples. As shown in FIG. 1, the plurality of electrodes 12 include a first electrode 12A, a second electrode 12B, and a third electrode 12C. Each of the first electrode 12A, the second electrode 12B, and the third electrode 12C extends in the third direction y. The first electrode 12A, the second electrode 12B, and the third electrode 12C are arranged side by side along the second direction x. The second electrode 12B is located next to the first electrode 12A in the second direction x. The third electrode 12C is located opposite to the first electrode 12A across the second electrode 12B.

As shown in FIGS. 3 and 4, the passivation film 20 covers the obverse surface 11A of the main body 11 and a portion of each electrode 12. The passivation film 20 is a thin film containing silicon dioxide (SiO₂) or silicon nitride (Si₃N₄), or a laminate of such thin films.

As shown in FIGS. 2 to 4, the passivation film 20 has a plurality of openings 21. The openings 21 penetrate in the first direction z. Each of the first electrode 12A, the second electrode 12B, and the third electrode 12C is exposed from one of the openings 21.

As shown in FIGS. 3 and 4, the second protective film 32 is located between the main body 11 and the first protective film 31 in the first direction z. The second protective film 32 covers a portion of each electrode 12, and the passivation film 20. The second protective film 32 is an insulator containing an organic compound. The second protective film 32 is made of a material containing polyimide. The second protective film 32 includes portions located between the passivation film 20 and the plurality of redistribution wirings 40. As shown in FIG. 3, the second protective film 32 has second openings 321 penetrating in the first direction z. As viewed in the first direction z, each second opening 321 overlaps with one of the openings 21 of the passivation film 20. In the semiconductor element A10, each second opening 321 exposes one of the electrodes 12. In the semiconductor element A10, one of the second openings 321 exposes the first electrode 12A.

As shown in FIGS. 3 and 4, the redistribution wirings 40 are located between the electrodes 12 and the terminals 50 in the first direction z. Each of the redistribution wirings 40 electrically conducts to one of the electrodes 12. Each of the redistribution wirings 40 includes a barrier layer that is in contact with at least one of the electrodes 12 and the second protective film 32, a seed layer deposited on the barrier layer, and a plating layer deposited on the seed layer. The barrier layer contains titanium (Ti). Each of the seed layer and the plating layer contains copper (Cu).

As shown in FIGS. 3 and 4, at least one of the redistribution wirings 40 has a main portion 41, a contact portion 42, and a dented portion 43. The contact portion 42 is electrically connected to one of the electrodes 12. In the semiconductor element A10, the contact portion 42 is electrically connected to the first electrode 12A. The contact portion 42 is in contact with the second protective film 32 and housed in a second opening 321 of the second protective film 32. As viewed in the first direction z, the entirety of the contact portion 42 overlaps with one of the openings 21 of the passivation film 20. The main portion 41 is located opposite to the electrodes 12 across the contact portion 42 in the first direction z. The contact portion 42 is connected to the main portion 41. The main portion 41 is sandwiched between the first protective film 31 and the second protective film 32. The dented portion 43 is recessed in the first direction z from the side of the main portion 41 that faces the first protective film 31 in the first direction z. As viewed in the first direction z, the dented portion 43 overlaps with the contact portion 42. The first protective film 31 is received in the dented portion 43.

As shown in FIGS. 3 and 4, the first protective film 31 covers the second protective film 32 and the redistribution wirings 40. The first protective film 31 is an insulator containing an organic compound. The first protective film 31 is made of a material containing polyimide. In the semiconductor element A10, the composition of the first protective film 31 is the same as that of the second protective film 32. The first protective film 31 is in contact with the terminals 50. The dimension in the first direction z of the first protective film 31 is greater than the dimension in the first direction z of the second protective film 32. The first protective film 31 has first openings 311 penetrating in the first direction z. Each first opening 311 exposes the main portion 41 of one of the redistribution wirings 40. A portion of one of the terminals 50 is housed in each first opening 311.

As shown in FIGS. 3 and 4, each of the terminals 50 is located opposite to the main body 11 with respect to the electrodes 12 and the redistribution wirings 40 in the first direction z. Each of the terminals 50 is electrically connected to the main portion 41 of one of the redistribution wirings 40. Thus, each of the terminals 50 electrically conducts to one of the electrodes 12. The terminals 50 contain copper. As shown in FIG. 1, in the semiconductor element A10, the plurality of terminals 50 are arranged in a grid pattern as viewed in the first direction Z.

As shown in FIGS. 3 and 4, each of the terminals 50 has a first portion 51 and a second portion 52. The first portion 51 is housed in a first opening 311 of the first protective film 31. The second portion 52 is connected to the first portion 51 and protrudes from the first opening 311. As shown in FIG. 2, as viewed in the first direction z, the second portion 52 is located outside the first opening 311.

As shown in FIGS. 3 and 4, the first portion 51 has a first surface 511 and a first peripheral surface 512. The first surface 511 faces the side where the electrodes 12 and the redistribution wirings 40 are located in the first direction z. The first surface 511 is electrically connected to the main portion 41 of one of the redistribution wirings 40. The first peripheral surface 512 surrounds the first surface 511 as viewed in the first direction z. The first peripheral surface 512 is in contact with the first protective film 31. The first peripheral surface 512 is inclined with respect to each of the second direction x and the third direction y. The cross-sectional area of the first portion 51 in a direction orthogonal to the first direction z decreases from the second portion 52 toward the first surface 511.

As shown in FIGS. 3 and 4, the second portion 52 has a second surface 521 and a second peripheral surface 522. The second surface 521 faces away from the first surface 511 of the first portion 51 in the first direction z. The second surface 521 is covered with one of the bonding layers 60. The second peripheral surface 522 surrounds the second surface 521 as viewed in the first direction z. The second peripheral surface 522 is exposed to the outside of the semiconductor element A10. The second peripheral surface 522 is inclined with respect to each of the second direction x and the third direction y. The cross-sectional area of the second portion 52 in a direction orthogonal to the first direction z decreases from the second surface 521 toward the first portion 51. As viewed in the first direction z, the entirety of the first peripheral surface 512 of the first portion 51 is located inwardly of the second peripheral surface 522.

As shown in FIGS. 3 and 4, in each of the second direction x and the third direction y, the dimension D1 of the periphery of the first surface 511 of the first portion 51 is smaller than the dimension D2 of the periphery of the second surface 521 of the second portion 52. The dimension D1 is equal to or greater than 40% and equal to or less than 60% of the dimension D2.

As shown in FIGS. 2 to 4, each of the terminals 50 has a first recess 53 recessed from the second surface 521 of the second portion 52. A portion of one of the bonding layers 60 is housed in the first recess 53.

As shown in FIG. 3, each of the bonding layers 60 is located opposite to the first surface 511 across the second surface 521 of one of the terminals 50 in the first direction z. The bonding layers 60 electrically conduct to the terminals 50, respectively. The bonding layers 60 contain a metal. The bonding layers 60 are solder. Therefore, the composition of the bonding layers 60 includes tin. The melting point of the bonding layers 60 is lower than the melting point of the terminals 50.

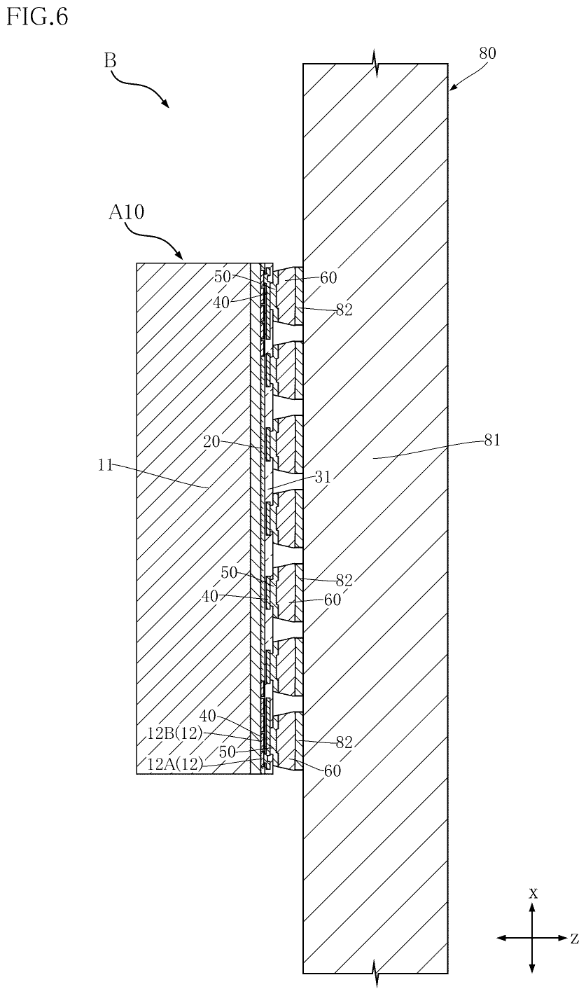

Next, the semiconductor device B in which the semiconductor element A10 is mounted will be described based on FIG. 6.

As shown in FIG. 6, the semiconductor device B includes the semiconductor element A10 and a base 80. The semiconductor element A10 is mounted on the base 80. The base 80 includes a substrate 81 and conductive parts 82. The substrate 81 is an insulator. The conductive parts 82 contain copper, for example. Each of the terminals 50 of the semiconductor element A10 is conductively bonded to a conductive part 82 via one of the bonding layers 60. Thus, the electrodes 12 of the semiconductor elements A10 electrically conduct to the conductive parts 82.

In the semiconductor device B, the base 80 is a wiring board. Alternatively, the base 80 may include only the conductive parts 82 that are leads. The base 80 may include an external terminal located opposite to the conductive parts 82 with respect to the substrate 81 in the first direction z. In the semiconductor device B, the semiconductor element A10 may be covered with scaling resin such as underfill.

Next, the effects of the semiconductor element A10 will be described.

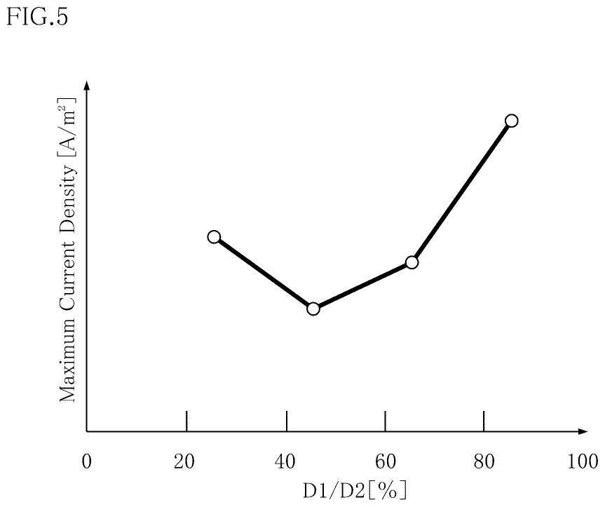

The semiconductor element A10 includes the main body 11, the electrode 12, the terminal 50, and the bonding layer 60. The bonding layer 60 contains a metal. The terminal 50 has the first surface 511 and the second surface 521. The bonding layer 60 is located opposite to the first surface 511 across the second surface 521. In the second direction x, the dimension D1 of the periphery of the first surface 511 is equal to or greater than 40% and equal to or less than 60% of the dimension D2 of the periphery of the second surface 521. Referring now to FIG. 5, the figure shows the change in the maximum current density at the terminal 50. The horizontal axis of FIG. 5 shows the ratio [%] of the dimension D1 to the dimension D2. The vertical axis of FIG. 5 shows the maximum current density [A/m²] at the terminal 50, where the unit length is along the first direction z. According to FIG. 5, the inventor has confirmed that the maximum current density at the terminal 50 is relatively low when the ratio of the dimension D1 to the dimension D2 is equal to or greater than 40% and equal to or less than 60%. That is, the present configuration reduces the maximum current density in the terminal 50, and hence suppresses the occurrence of cracks in the bonding layer 60 due to electromigration. Therefore, according to the present configuration, it is possible to suppress the occurrence of cracks in the bonding layer 60 due to electromigration in the semiconductor element A10.

The semiconductor element A10 also includes the redistribution wiring 40 and the first protective film 31. The first protective film 31 has the first opening 311 penetrating in the first direction z and exposing the redistribution wiring 40. The terminal 50 has the first portion 51 including the first surface 511 and housed in the first opening 311, and the second portion 52 including the second surface 521 and protruding from the first opening 311. As viewed in the first direction z, the second portion 52 is located outside the first opening 311. With such a configuration, the redistribution wiring 40 and the first portion 51 are protected by the first protective film 31, and excessive changes in the current density at the terminal 50 can be suppressed.

The first portion 51 has the first peripheral surface 512 surrounding the first surface 511 as viewed in the first direction z. The first peripheral surface 512 is inclined with respect to the second direction x. The cross-sectional area of the first portion 51 in a direction orthogonal to the first direction z decreases from the second portion 52 toward the first surface 511. With such a configuration, the distribution of current density in the first portion 51 can be made uniform.

The second portion 52 has the second peripheral surface 522 surrounding the second surface 521 as viewed in the first direction z. The second peripheral surface 522 is inclined with respect to the second direction x. The cross-sectional area of the second portion 52 in a direction orthogonal to the first direction z decreases from the second surface 521 toward the first portion 51. With such a configuration, the distribution of current density in the second portion 52 can be made uniform.

As viewed in the first direction z, the entirety of the first peripheral surface 512 of the first portion 51 is located inwardly of the second peripheral surface 522 of the second portion 52. With such a configuration, the distribution of current density at the interface between the first portion 51 and the second portion 52 can be made uniform.

### Second Embodiment

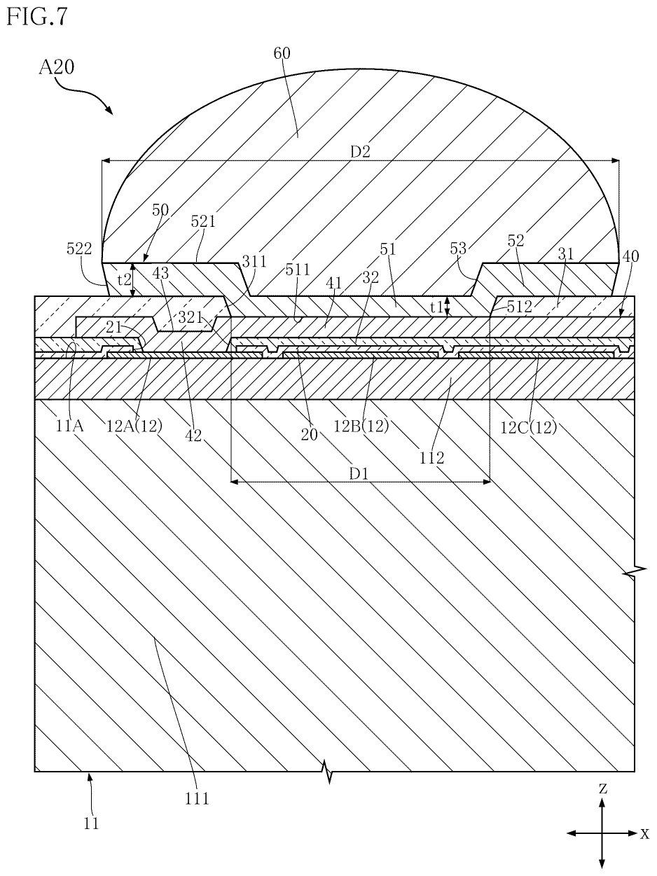

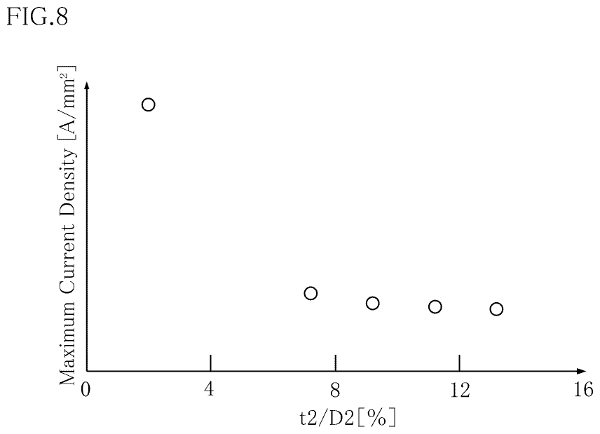

A semiconductor element A20 according to a second embodiment of the present disclosure will be described based on FIGS. 7 and 8. In these figures, the elements that are identical or similar to those of the semiconductor element A10 described above are denoted by the same reference signs, and the descriptions thereof are omitted. Incidentally, FIG. 7 corresponds to FIG. 3 that shows the semiconductor element A10.

The semiconductor element A20 differs from the semiconductor element A10 in the configuration of the terminals 50.

As shown in FIG. 7, in each of the terminals 50, the dimension t2 of the second portion 52 in the first direction z is greater than the dimension t1 of the first portion 51 in the first direction z. The dimension t2 is equal to or greater than 5% of the dimension D2 in each of the second direction x and the third direction y of the periphery of the second surface 521 of the second portion 52.

Next, the effects of the semiconductor element A20 will be described.

The semiconductor element A20 includes the main body 11, the electrode 12, the terminal 50, and the bonding layer 60. The bonding layer 60 contains a metal. The terminal 50 has the first surface 511 and the second surface 521. The bonding layer 60 is located opposite to the first surface 511 across the second surface 521. In the second direction x, the dimension D1 of the periphery of the first surface 511 is equal to or greater than 40% and equal to or less than 60% of the dimension D2 of the periphery of the second surface 521. With such a configuration, it is possible to suppress the occurrence of cracks in the bonding layer 60 due to electromigration in the semiconductor element A20 as well. The semiconductor element A20 has a configuration in common with the semiconductor element A10, thereby achieving the same effect as the semiconductor element A10.

In the terminals 50 of the semiconductor element A20, the dimension t2 of the second portion 52 in the first direction z is greater than the dimension t1 of the first portion 51 in the first direction z. The dimension t2 is equal to or greater than 5% of the dimension D2 in the second direction x of the periphery of the second surface 521 of the second portion 52. Referring now to FIG. 8, the figure shows the change in the maximum current density at the terminal 50. The horizontal axis of FIG. 8 shows the ratio [%] of the dimension t2 to the dimension D2. The vertical axis of FIG. 8 shows the maximum current density [A/mm²] at the terminal 50, where the unit length is along the first direction z. According to FIG. 8, the inventor has confirmed that the maximum current density at the terminal 50 is relatively low when the ratio of dimension t2 to dimension D2 exceeds 4%. That is, the present configuration reduces the maximum current density in the terminal 50, and hence suppresses the occurrence of cracks in the bonding layer 60 due to electromigration.

### Third Embodiment

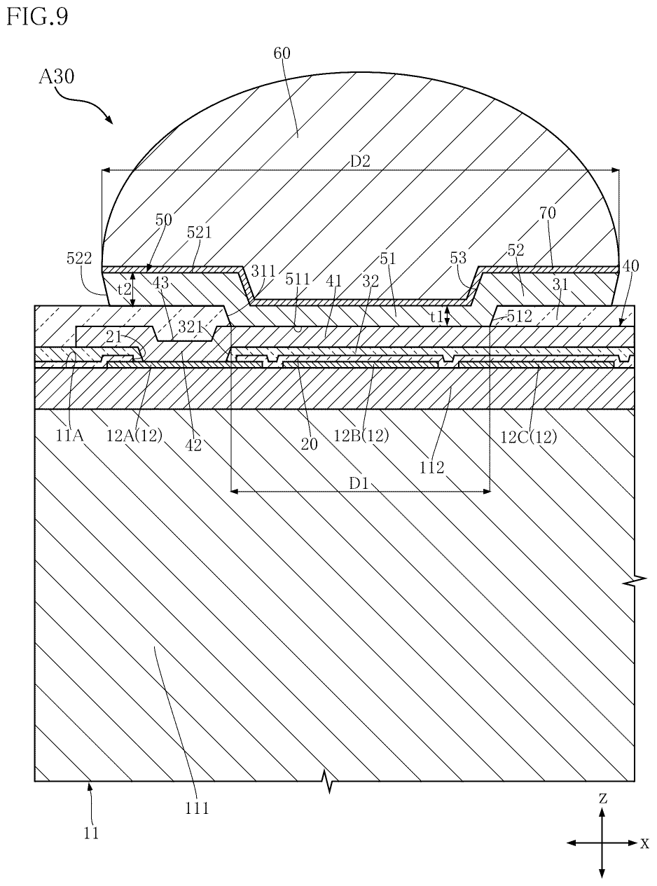

A semiconductor element A30 according to a third embodiment of the present disclosure will be described based on FIG. 9. In these figures, the elements that are identical or similar to those of the semiconductor element A10 described above are denoted by the same reference signs, and the descriptions thereof are omitted. Incidentally, FIG. 9 corresponds to FIG. 3 that shows the semiconductor element A10.

The semiconductor element A30 differs from the semiconductor element A20 in that the semiconductor element A30 further includes intermediate layers 70.

As shown in FIG. 9, each intermediate layer 70 is located between the second surface 521 of one of the terminals 50 and one of the bonding layers 60. Each intermediate layer 70 is in contact with a second surface 521, the surface of one of the terminals 50 that defines the first recess 53, and one of the bonding layers 60. The intermediate layers 70 contain a metal. The composition of the intermediate layers 70 includes nickel (Ni).

Next, the effects of the semiconductor element A30 will be described.

The semiconductor element A30 includes the main body 11, the electrode 12, the terminal 50, and the bonding layer 60. The bonding layer 60 contains a metal. The terminal 50 has the first surface 511 and the second surface 521. The bonding layer 60 is located opposite to the first surface 511 across the second surface 521. In the second direction x, the dimension D1 of the periphery of the first surface 511 is equal to or greater than 40% and equal to or less than 60% of the dimension D2 of the periphery of the second surface 521. With such a configuration, it is possible to suppress the occurrence of cracks in the bonding layer 60 due to electromigration in the semiconductor element A30 as well. The semiconductor element A30 has a configuration in common with the semiconductor element A10, thereby achieving the same effect as the semiconductor element A10.

The semiconductor element A30 further includes the intermediate layer 70 located between the second surface 521 of the terminal 50 and the bonding layer 60. The composition of the intermediate layer 70 includes nickel. The intermediate layer 70 is in contact with each of the second surface 521 and the bonding layer 60. With such a configuration, when the semiconductor element A30 is mounted on the base 80 shown in FIG. 6, eutectic metal is formed by the intermediate layer 70 and the molten bonding layer 60. The eutectic metal increases the tensile strength of the bonding layer 60. This effectively suppresses the occurrence of cracks in the bonding layer 60 due to electromigration.

### Fourth Embodiment

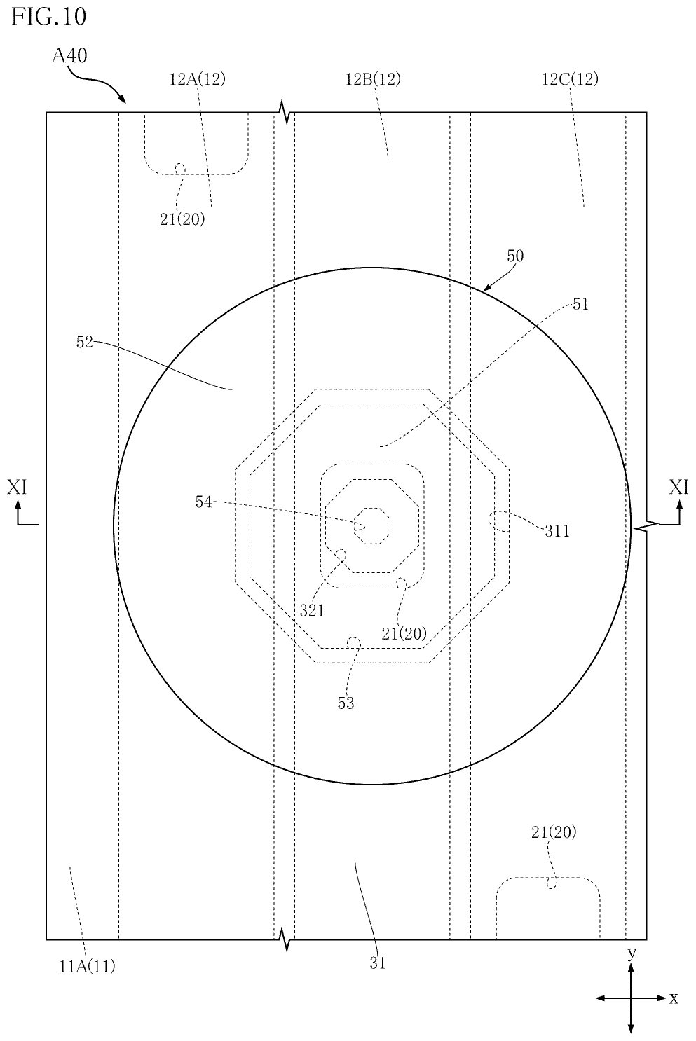

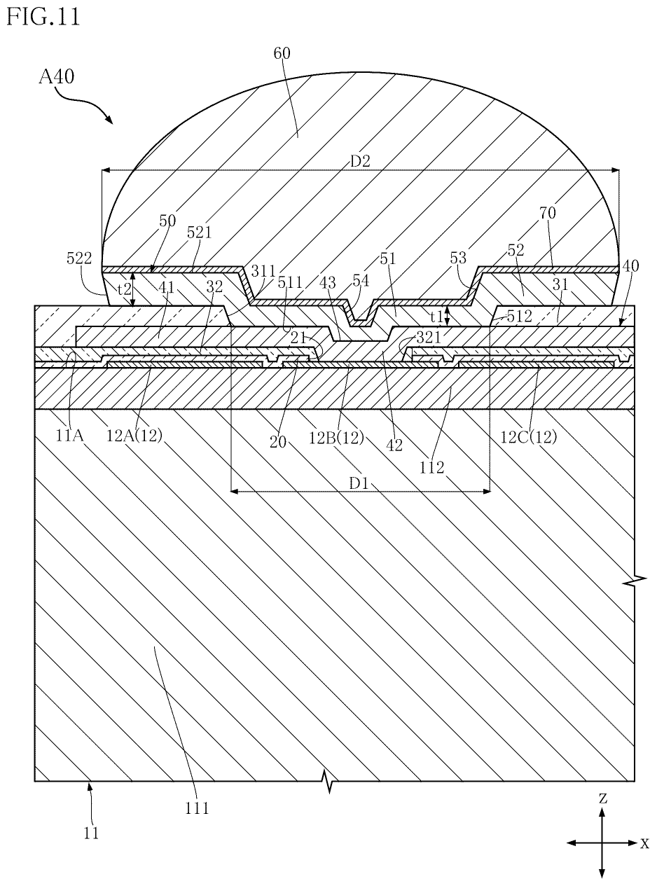

A semiconductor element A40 according to a fourth embodiment of the present disclosure will be described based on FIGS. 10 and 11. In these figures, the elements that are identical or similar to those of the semiconductor element A10 described above are denoted by the same reference signs, and the descriptions thereof are omitted. For the convenience of understanding, the bonding layer 60 is transparent in FIG. 10. Incidentally, FIG. 10 corresponds to FIG. 2 that shows the semiconductor element A10.

The semiconductor element A40 differs from the semiconductor element A30 in the configurations of the second protective film 32, the redistribution wirings 40, and the terminals 50.

As shown in FIGS. 10 and 11, one of the second openings 321 of the second protective film 32 exposes the second electrode 12B. As viewed in the first direction z, the second opening 321 overlaps with one of the openings 21 of the passivation film 20 that exposes the second electrode 12B. The contact portion 42 of one of the redistribution wirings 40 is electrically connected to the second electrode 12B. The contact portion 42 is housed in the second opening 321.

As shown in FIG. 11, the first portion 51 of each of the terminals 50 is received in the dented portion 43 of one of the redistribution wirings 40. Each of the terminals 50 has a second recess 54. The second recess 54 is recessed in the first direction z from the surface of the terminal 50 that defines the first recess 53. A portion of one of the bonding layers 60 is housed in the second recess 54. The intermediate layer 70 is in contact with the surface of the terminal 50 that defines the second recess 54. As shown in FIG. 10, as viewed in the first direction z, the second recess 54 is located inwardly of the second opening 321 of the second protective film 32.

Next, the effects of the semiconductor element A40 will be described.

The semiconductor element A40 includes the main body 11, the electrode 12, the terminal 50, and the bonding layer 60. The bonding layer 60 contains a metal. The terminal 50 has the first surface 511 and the second surface 521. The bonding layer 60 is located opposite to the first surface 511 across the second surface 521. In the second direction x, the dimension D1 of the periphery of the first surface 511 is equal to or greater than 40% and equal to or less than 60% of the dimension D2 of the periphery of the second surface 521. With such a configuration, it is possible to suppress the occurrence of cracks in the bonding layers 60 due to electromigration in the semiconductor element A40 as well. The semiconductor element A40 has a configuration in common with the semiconductor element A10, thereby achieving the same effect as the semiconductor element A10.

In the semiconductor element A40, each terminal 50 has a second recess 54 recessed in the first direction z from the surface defining the first recess 53. A portion of a bonding layer 60 is housed in the second recess 54. Such a configuration enhances the anchoring effect of the bonding layer 60 for the terminal 50, so that the bonding strength of the bonding layer 60 to the terminal 50 is increased.

In the semiconductor element A40, the first portion 51 of the terminal 50 is received in the dented portion 43 of the redistribution wiring 40. Such a configuration reduces the electrical resistance at the interface between the redistribution wiring 40 and the terminal 50.

### Fifth Embodiment

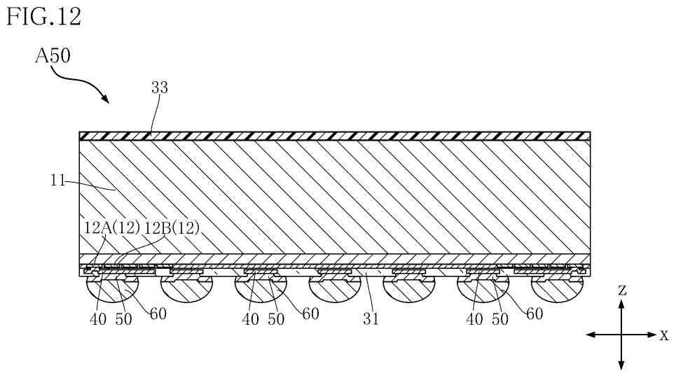

A semiconductor element A50 according to a fifth embodiment of the present disclosure will be described based on FIG. 12. In these figures, the elements that are identical or similar to those of the semiconductor element A10 described above are denoted by the same reference signs, and the descriptions thereof are omitted. Incidentally, FIG. 12 corresponds to FIG. 6 that shows the semiconductor element A10 constituting the semiconductor device B.

The semiconductor element A50 differs from the semiconductor element A10 in that the semiconductor element A50 further includes a third protective film 33.

As shown in FIG. 12, the third protective film 33 is located opposite to the electrodes 12 across the main body 11 in the first direction z. The third protective film 33 covers one side of the main body 11 in the first direction z. The third protective film 33 is made of a material containing, for example, an epoxy resin.

Next, the effects of the semiconductor element A50 will be described.

The semiconductor element A50 includes the main body 11, the electrode 12, the terminal 50, and the bonding layer 60. The bonding layer 60 contains a metal. The terminal 50 has the first surface 511 and the second surface 521. The bonding layer 60 is located opposite to the first surface 511 across the second surface 521. In the second direction x, the dimension D1 of the periphery of the first surface 511 is equal to or greater than 40% and equal to or less than 60% of the dimension D2 of the periphery of the second surface 521. With such a configuration, it is possible to suppress the occurrence of cracks in the bonding layers 60 due to electromigration in the semiconductor element A50 as well. The semiconductor element A50 has a configuration in common with the semiconductor element A10, thereby achieving the same effect as the semiconductor element A10.

The semiconductor element A50 further includes a third protective film 33 located opposite to the electrodes 12 across the main body 11 in the first direction z, and the third protective film 33 covers one side of the main body 11 in the first direction z. With such a configuration, warping of the main body 11 in the first direction z can be reduced during the manufacture of the semiconductor element A50.

The present disclosure is not limited to the above-described embodiments. Various modification in design may be made freely in the specific structure of each part of the present disclosure.

The present disclosure includes the embodiments described in the following clauses.

### Clause 1.

A semiconductor element (A10) comprising:
a main body (11) including a semiconductor layer (112);
an electrode (12) located on one side of the main body (11) in a first direction and electrically conducting to the semiconductor layer (112);
a terminal (50) located opposite to the main body (11) with respect to the electrode (12) in the first direction and electrically conducting to the electrode (12); and
a bonding layer (60) electrically conducting to the terminal (50), wherein
the bonding layer (60) contains a metal,
the terminal (50) includes a first surface (511) facing a side where the electrode (12) is located in the first direction, and a second surface (521) facing away from the first surface (511) in the first direction,
the bonding layer (60) is located opposite to the first surface (511) across the second surface (521), and
in a second direction orthogonal to the first direction, a dimension (D1) of a periphery of the first surface (511) is equal to or greater than 40% and equal to or less than 60% of a dimension (D2) of a periphery of the second surface (521).

### Clause 2.

The semiconductor element (A10) according to clause 1, wherein composition of the bonding layer (60) includes tin.

### Clause 3.

The semiconductor element (A10) according to clause 2,
further comprising a redistribution wiring (40) located between the electrode (12) and the terminal (50) in the first direction, wherein the redistribution wiring (40) electrically conducts to the electrode (12) and the terminal (50).

### Clause 4.

The semiconductor element (A10) according to clause 3, wherein each of the first surface (511) and the electrode (12) is electrically connected to the redistribution wiring (40).

### Clause 5.

The semiconductor element (A10) according to clause 4,
further comprising a first protective film (31) covering the redistribution wiring (40), wherein
the first protective film (31) is formed with a first opening (311) penetrating in the first direction and exposing the redistribution wiring (40), and
a portion of the terminal (50) is housed in the first opening (311).

### Clause 6.

The semiconductor element (A10) according to clause 5, wherein the terminal (50) includes a first portion (51) including the first surface (511) and housed in the first opening (311), and a second portion (52) including the second surface (521) and protruding from the first opening (311), and
the second portion (52) is located outside the first opening (311) as viewed in the first direction.

### Clause 7.

The semiconductor element (A10) according to clause 6, wherein the first portion (51) includes a first peripheral surface (512) surrounding the first surface (511) as viewed in the first direction, and
the first peripheral surface (512) is in contact with the first protective film (31).

### Clause 8.

The semiconductor element (A10) according to clause 7, wherein the first peripheral surface (512) is inclined with respect to the second direction, and
a cross-sectional area of the first portion (51) in a direction orthogonal to the first direction decreases from the second portion (52) toward the first surface (511).

### Clause 9.

The semiconductor element (A10) according to clause 8, wherein the second portion (52) includes a second peripheral surface (522) surrounding the second surface (521) as viewed in the first direction, and
the first peripheral surface (512) is entirely located inwardly of the second peripheral surface (522) as viewed in the first direction.

### Clause 10.

The semiconductor element (A10) according to clause 9, wherein the second peripheral surface (522) is inclined with respect to the second direction, and
a cross-sectional area of the second portion (52) in a direction orthogonal to the first direction decreases from the second surface (521) toward the first portion (51).

### Clause 11.

The semiconductor element (A20) according to clause 10, wherein a dimension (t2) of the second portion (52) in the first direction is greater than a dimension (t1) of the first portion (51) in the first direction.

### Clause 12.

The semiconductor element (A20) according to clause 11, wherein the dimension (t2) of the second portion (52) in the first direction is equal to or greater than 5% of the dimension (D2) of the periphery of the second surface (521) in the second direction.

### Clause 13.

The semiconductor element (A30) according to clause 12, further comprising an intermediate layer (70) located between the second surface (521) and the bonding layer (60), wherein
the intermediate layer (70) contains a metal, and
the intermediate layer (70) is in contact with each of the second surface (521) and the bonding layer (60).

### Clause 14.

The semiconductor element (A30) according to clause 13, wherein composition of the intermediate layer (70) includes nickel.

### Clause 15.

The semiconductor element (A10) according to any one of clauses 5 to 14, wherein the terminal (50) includes a first recess (53) recessed from the second surface (521), and
a portion of the bonding layer (60) is housed in the first recess (53).

### Clause 16.

The semiconductor element (A10) according to clause 15, further comprising a second protective film (32) located between the main body (11) and the redistribution wiring (40) in the first direction, wherein
the second protective film (32) includes a second opening (321) penetrating in the first direction and exposing the electrode (12), and
a portion of the redistribution wiring (40) is housed in the second opening (321).

### Clause 17.

The semiconductor element (A10) according to clause 16, wherein the first recess (53) overlaps with the second opening (321) as viewed in the first direction.

### Clause 18.

The semiconductor element (A40) according to clause 17, wherein the terminal (50) includes a second recess (54) recessed in the first direction from a surface of the terminal (50) that defines the first recess (53), and
a portion of the bonding layer (60) is housed in the second recess (54).

### Clause 19.

A semiconductor device (B) comprising:
the semiconductor element (A10) as set forth in clause 15, and
a base (80) that includes a conductive part (82), wherein
the semiconductor element (A10) is mounted on the base (80), and
the terminal (50) is conductively bonded to the conductive part (82) via the bonding layer (60).

### Clause 20.

The semiconductor element (A10) according to clause 16, wherein each of the first protective film (31) and the second protective film (32) contains polyimide.

### Clause 21.

The semiconductor element (A10) according to clause 16, wherein a dimension of the first protective film (31) in the first direction is greater than the second dimension (32) of the second protective film.

### Clause 22.

The semiconductor element (A10) according to clause 16, wherein the redistribution wiring (40) includes a main portion (41) located between the first protective film (31) and the second protective film (32), and a contact portion (42) connected to the main portion (41),
the electrode (12) is electrically connected to the contact portion (42) and in contact with the second protective film (32), and
the first surface (511) is electrically connected to the main portion (41).

### Clause 23.

The semiconductor element (A10) according to clause 22, wherein the contact portion (42) is housed in the second opening (321).

### Clause 24.

The semiconductor element (A10) according to clause 23, wherein the redistribution wiring (40) includes a dented portion (43) recessed from the main portion (41) in a first direction,
the dented portion (43) overlaps with the contact portion (42) as viewed in the first direction, and
the first protective film (31) is received in the dented portion (43).

### Clause 25.

The semiconductor element (A40) according to clause 18, wherein the redistribution wiring (40) includes a dented portion (43) recessed from one side in a first direction, and
a part of the first portion (51) is received in the dented portion (43).

### Clause 26.

The semiconductor element (A40) according to clause 18, wherein the second recess (54) is located inwardly of the second opening (321) as viewed in the first direction.

### Clause 27.

The semiconductor element (A50) according to clause 16, further comprising a third protective film (33) located opposite to the electrode (12) across the main body (11),
wherein the third protective film (33) covers one side of the main body (11) in the first direction.

REFERENCE NUMERALS

| | |
|---|---|
| A10 to A50: Semiconductor element | B: Semiconductor device |
| 11: Main body | 11A: Obverse surface |
| 111: Semiconductor substrate | 112: Semiconductor layer |
| 12: Electrode | 12A, 12B, 12C: First electrode, |
| | Second electrode, Third electrode |
| 20: Passivation film | 21: Opening |
| 31: First protective film | 311: First opening |
| 32: Second protective film | 321: Second opening |
| 33: Third protective film | 40: Redistribution wiring |
| 41: Main portion | 42: Contact portion |
| 43: Dented portion | 50: Terminal |
| 51: First portion | 511: First surface |
| 512: First peripheral surface | 52: Second portion |
| 521: Second surface | 522: Second peripheral surface |
| 53, 54: First recess, Second recess | 60: Bonding layer |
| 70: Intermediate layer | 80: Base |
| 81: Substrate | 82: Conductive part |
| z, x, y: First direction, Second | |
| direction, Third direction | |

1. A semiconductor element comprising:
a main body including a semiconductor layer;
an electrode located on one side of the main body in a first direction and electrically conducting to the semiconductor layer;
a terminal located opposite to the main body with respect to the electrode in the first direction and electrically conducting to the electrode; and
a bonding layer electrically conducting to the terminal, wherein
the bonding layer contains a metal,
the terminal includes a first surface facing a side where the electrode is located in the first direction, and a second surface facing away from the first surface in the first direction,
the bonding layer is located opposite to the first surface across the second surface, and
in a second direction orthogonal to the first direction, a dimension of a periphery of the first surface is equal to or greater than 40% and equal to or less than 60% of a dimension of a periphery of the second surface.

2. The semiconductor element according to claim 1, wherein composition of the bonding layer includes tin.

3. The semiconductor element according to claim 2, further comprising a redistribution wiring located between the electrode and the terminal in the first direction,
wherein the redistribution wiring electrically conducts to the electrode and the terminal.

4. The semiconductor element according to claim 3, wherein each of the first surface and the electrode is electrically connected to the redistribution wiring.

5. The semiconductor element according to claim 4, further comprising a first protective film covering the redistribution wiring, wherein
the first protective film is formed with a first opening penetrating in the first direction and exposing the redistribution wiring, and
a portion of the terminal is housed in the first opening.

6. The semiconductor element according to claim 5, wherein the terminal includes a first portion including the first surface and housed in the first opening, and a second portion including the second surface and protruding from the first opening, and
the second portion is located outside the first opening as viewed in the first direction.

7. The semiconductor element according to claim 6, wherein the first portion includes a first peripheral surface surrounding the first surface as viewed in the first direction, and
the first peripheral surface is in contact with the first protective film.

8. The semiconductor element according to claim 7, wherein the first peripheral surface is inclined with respect to the second direction, and
a cross-sectional area of the first portion in a direction orthogonal to the first direction decreases from the second portion toward the first surface.

9. The semiconductor element according to claim 8, wherein the second portion includes a second peripheral surface surrounding the second surface as viewed in the first direction, and
the first peripheral surface is entirely located inwardly of the second peripheral surface as viewed in the first direction.

10. The semiconductor element according to claim 9, wherein the second peripheral surface is inclined with respect to the second direction, and
a cross-sectional area of the second portion in a direction orthogonal to the first direction decreases from the second surface toward the first portion.

11. The semiconductor element according to claim 10, wherein a dimension of the second portion in the first direction is greater than a dimension of the first portion in the first direction.

12. The semiconductor element according to claim 11, wherein the dimension of the second portion in the first direction is equal to or greater than 5% of the dimension of the periphery of the second surface in the second direction.

13. The semiconductor element according to claim 12, further comprising an intermediate layer located between the second surface and the bonding layer, wherein
the intermediate layer contains a metal, and
the intermediate layer is in contact with each of the second surface and the bonding layer.

14. The semiconductor element according to claim 13, wherein composition of the intermediate layer includes nickel.

15. The semiconductor element according to claim 5, wherein the terminal includes a first recess recessed from the second surface, and
a portion of the bonding layer is housed in the first recess.

16. The semiconductor element according to claim 15, further comprising a second protective film located between the main body and the redistribution wiring in the first direction, wherein
the second protective film includes a second opening penetrating in the first direction and exposing the electrode, and
a portion of the redistribution wiring is housed in the second opening.

17. The semiconductor element according to claim 16, wherein the first recess overlaps with the second opening as viewed in the first direction.

18. The semiconductor element according to claim 17, wherein the terminal includes a second recess recessed in the first direction from a surface of the terminal that defines the first recess, and
a portion of the bonding layer is housed in the second recess.

19. A semiconductor device comprising:
the semiconductor element as set forth in claim 15, and
a base that includes a conductive part, wherein
the semiconductor element is mounted on the base, and
the terminal is conductively bonded to the conductive part via the bonding layer.
